(19) United States
(12) Patent Application Publication
(10) Pub. No.: US 2018/0210281 A1
(43) Pub. Date: Jul. 26, 2018

(54) METHOD FOR MANUFACTURING A DISPLAY SUBSTRATE

(71) Applicants: BOE TECHNOLOGY GROUP CO., LTD., Beijing (CN); CHENGDU BOE OPTOELECTRONICS TECHNOLOGY CO., LTD., Sichuan Province (CN)

(72) Inventors: Jinjie LIU, Beijing (CN); Qingde LONG, Beijing (CN); Xing LIU, Beijing (CN); Tang YANG, Beijing (CN)

(73) Assignees: BOE TECHNOLOGY GROUP CO., LTD., Beijing (CN); CHENGDU BOE OPTOELECTRONICS TECHNOLOGY CO., LTD., Sichuan Province (CN)

(21) Appl. No.: 15/720,888

(22) Filed: Sep. 29, 2017

(30) Foreign Application Priority Data
Jan. 24, 2017 (CN) 201710060160.9

(51) Int. Cl. G02F 1/1335; H01L 21/027; G02F 1/1362; H01L 21/47; H01L 21/308

(52) U.S. Cl. CPC G02F 1/133514; G02F 1/133512; H01L 21/0273; H01L 21/308; G02F 1/136209; H01L 21/47; G02F 1/133553

(57) ABSTRACT

A method for manufacturing a display substrate is provided. The method for manufacturing the display substrate includes: subjecting the photoresist layer to a first exposing operation using a mask; moving the mask a first number of the first distances in the row direction and a second number of the second distances in the column direction, and subjecting the photoresist layer to a second exposing operation using the moved mask; and developing the photoresist layer to form a pattern having a plurality of opening structures.

### CROSS-REFERENCE TO RELATED APPLICATIONS

This application claims priority to Chinese Patent Application No. 201710060160.9 filed on Jan. 24, 2017, which is incorporated herein by reference in its entirety.

### TECHNICAL FIELD

At least one embodiment of the present disclosure relates to a method for manufacturing a display substrate.

### BACKGROUND

In the liquid crystal display device industry, manufacturing a black matrix on a base substrate is generally the first step in the preparing process of a color filter substrate. The black matrix may effectively intercept leaked light between sub-pixels, avoid a color mixture of color layers connected to each other, and reduce reflecting of external light, thus improving a contrast ratio of the display device, and the black matrix may also prevent the external light from irradiating an active layer of a thin film transistor component and increasing a leakage current.

### SUMMARY

The present disclosure provides in at least one embodiment a method for manufacturing a display substrate, a display substrate and a display device. A black matrix may be manufactured by the method for manufacturing the display substrate, even if a mask for manufacturing the black matrix is contaminated or slightly damaged, a defect in a fixed position (which is a common defect) will not occur, such that a problem that the black matrix generates light leakage or a bright spot at a pixel region or a bezel region may be effectively solved, thus effectively reducing the loss of utilization rate and increasing a yield of the black matrix during the process, saving costs and reducing risk.

The present disclosure provides in at least one embodiment a method for manufacturing the display substrate, including: applying a photoresist layer on a base substrate; subjecting the photoresist layer to a first exposing operation using a mask, wherein the mask includes a light transmitting portion and a plurality of light shielding portions, the plurality of light shielding portions is arranged in an array in a row direction and a column direction, the light shielding portions are arranged in the row direction at intervals of a first distance, and the light shielding portions are arranged in the column direction at intervals of a second distance; moving the mask a first number of the first distances in row direction and a second number of second distances in the column direction, and subjecting the photoresist layer to a second exposing operation using the moved mask; and developing the photoresist layer to form a pattern having a plurality of opening structures.

The present disclosure provides in at least one embodiment a display substrate manufactured by any one of the methods for manufacturing the display substrate according to the embodiments of the present disclosure.

The present disclosure provides in at least one embodiment a display device including any one of the display substrates according to the embodiments of the present disclosure.

### BRIEF DESCRIPTION OF THE DRAWINGS

In order to illustrate technical solutions according to embodiments of the present disclosure clearly, drawings for the description of the embodiments will be described briefly hereinafter. Apparently, the drawings described hereinafter are related to merely some embodiments of the present disclosure, and are not intended to limit the present disclosure.

FIG. 1 is a schematic diagram showing a method for manufacturing a black matrix of a display substrate;

FIG. 2a is a schematic diagram showing steps of a method for manufacturing a display substrate provided by the present disclosure in some embodiments;

FIG. 2b is a schematic diagram showing an exposure process in a method for manufacturing a black matrix of a display substrate provided by the present disclosure in some embodiments;

FIG. 3 is a schematic diagram showing an exposure process with foreign matters on a mask provided by the present disclosure in some embodiments; and

FIGS. 4a-4g are schematic diagrams showing process steps in a manufacturing flow of a black matrix provided by the present disclosure in some other embodiments.

### REFERENCE NUMERALS

10—photoresist layer; 11—opening structure; 20—mask; 21—light transmitting portion; 22—light shielding portion; 40—foreign matter; 41-foreign matter pattern; 50—ultraviolet rays; 100—photoresist layer; 101—opening structure; 1011—first light shielded region; 1012—second light shielded region; 200—mask; 201—light transmitting portion; 202—light shielding portion; 300—base substrate; 400—foreign matter; 401—first foreign matter shielded region; 402—second foreign matter shielded region; 500—ultraviolet rays; 600—black material layer; AA′—first distance; BB′—second distance.

### DETAILED DESCRIPTION

In order to make the objects, the technical solutions and the advantages of the present disclosure more clear, technical solutions of the embodiments of the present disclosure will be described hereinafter in a clear and complete manner in conjunction with the drawings of the embodiments of the present disclosure. Apparently, the following embodiments are merely a part of, rather than all of, the embodiments of the present disclosure, and based on these embodiments of the present disclosure, a person skilled in the art may obtain other embodiments without creative labors, which also fall within the scope of the present disclosure.

Unless otherwise defined, any technical or scientific terms used herein shall have the common meaning understood by a person of ordinary skills. Such words as “first” and “second” used in the present disclosure are merely used to differentiate different components rather than to indicate any order, number or importance. Such words as “comprises” or “includes” refers to that the element or the article appears in front of the word contain elements or articles following the word and equivalents thereof, rather than to exclude other elements or articles. Such words as “on/above”, “under/below”, “left” and “right” are merely used to represent relative position relationship, and when an absolute position of an object is changed, the relative position relationship may also be changed.

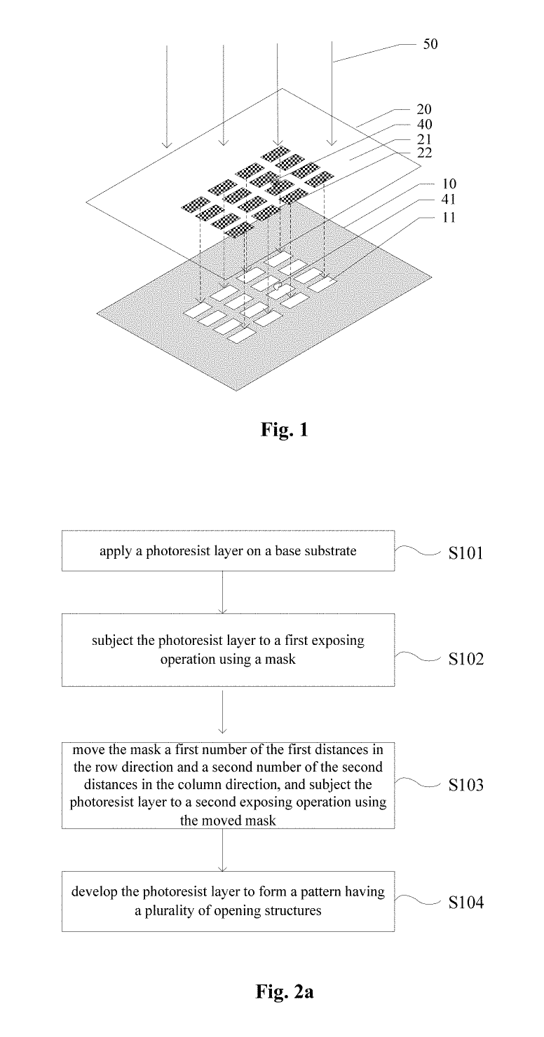

In a manufacturing process of a color filter substrate, a black matrix is generally manufactured on a base substrate of the color filter substrate first. The process for manufacturing the black matrix mainly consists of three steps: adhesive-applying, exposing and developing. FIG. 1 is a schematic diagram showing a method for manufacturing the black matrix of the display substrate. As shown in FIG. 1, a black photoresist layer 10 is applied on the base substrate, and the photoresist layer 10 is irradiated with ultraviolet rays 50 using a black matrix mask 20. For example, the photoresist layer 10 is a negative photoresist layer, and thus micromolecules located at an exposure region will turn into macromolecules, and cannot be dissolved by a developing solution after polymerized, therefore after being developed, the photoresist layer 10 located at the exposure region remains on the base substrate, while the photoresist layer 10 located at a non-exposure region is removed after being dissolved by the developing solution. The black matrix mask 20 has a light transmitting portion 21 and a plurality of light shielding portions 22 arranged in an array, and the ultraviolet rays 50 may penetrate through the light transmitting portion 21 of the mask 20 to irradiate a light transmitting region on the photoresist layer 10 formed by the light transmitting portion 21, therefore the photoresist layer 10 in this region is exposed and hardened, and will not be dissolved by the developing solution. The ultraviolet rays 50 are blocked by the light shielding portions 22 in the mask 20, and may not irradiate light shielded regions on the photoresist layer 10 formed by the light shielding portions 22. The photoresist layer 10 in these regions will be dissolved by the developing solution, and then removed. Therefore, a plurality of opening structures 11 overlaps the shielded regions on photoresist layer 10 formed by the light shielding portions 22 are formed, that is, a pattern having opening structures in the black matrix is formed.

In research, the applicant found that, in case that the light transmitting portion 21 of the black matrix mask 20 is contaminated or slightly damaged, regions of the photoresist layer 10 to be exposed may not be exposed due to being shielded by the foreign matter 40 during the exposure process, therefore in the developing process, the region shielded by the foreign matter 40 is dissolved by the developing solution, such that a foreign matter pattern 41 is formed on the photoresist layer 10, that is, a defect in a fixed position (which is a common defect) occurs. In case that the foreign matter pattern 41 is located at a pixel region, light leakage occurs at the pixel region, as shown in FIG. 1, and in case that the foreign matter pattern is located at a bezel region, a bright spot may be generated at the bezel region. A black matrix manufactured using a black matrix mask having defects may also generate defects, and therefore the loss of utilization rate may be generated. For the bright spot generated at the bezel region, a manual repairing operation (such as an ink repairing operation) is usually needed, which wastes resources.

The present disclosure provides in at least one embodiment a method for manufacturing a display substrate, a display substrate and a display device. The method for manufacturing the display substrate includes: applying a photoresist layer on a base substrate; subjecting the photoresist layer to a first exposing operation using a mask, wherein the mask includes a light transmitting portion and a plurality of light shielding portions, the plurality of light shielding portions is arranged in an array in a row direction and a column direction, the light shielding portion are arranged in the row direction at intervals of a first distance, and the light shielding portions are arranged in the column direction at intervals of a second distance; moving the mask a first number of the first distances in the row direction and a second number of the second distances in the column direction, and subjecting the photoresist layer to a second exposing operation using the moved mask; and developing the photoresist layer to form a pattern having a plurality of opening structures. A black matrix may be manufactured by the method for manufacturing the display substrate, even if a mask for manufacturing the black matrix is contaminated or slightly damaged, a defect in a fixed position may not occur, such that the problem that the black matrix generates light leakage or a bright spot at a pixel region or a bezel region may be effectively solved, thus effectively reducing the loss of utilization rate and increasing the yield of the black matrix during the process, saving costs and reducing risk.

The method for manufacturing the display substrate, the display substrate and the display device provided by the present disclosure in at least one embodiment will be described hereinafter in conjunction with the drawings.

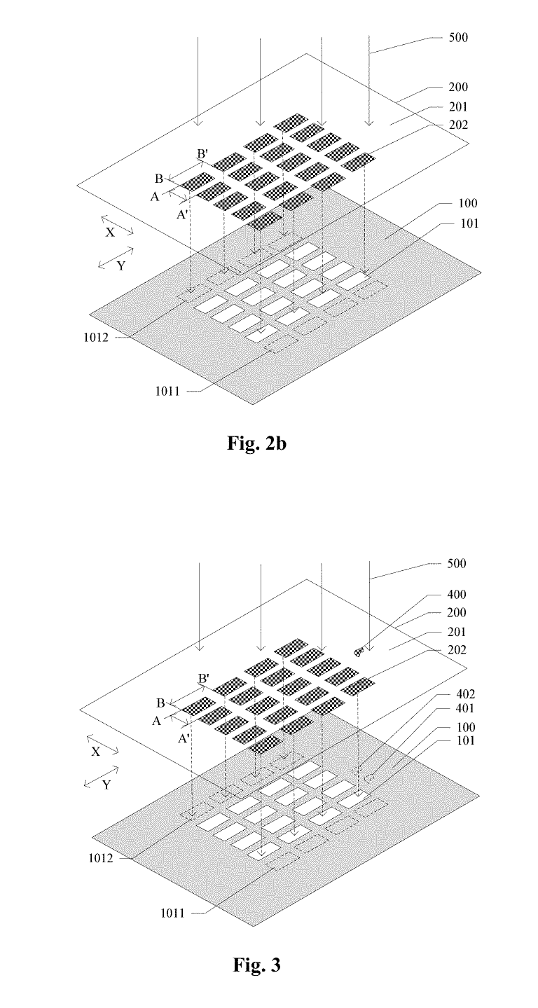

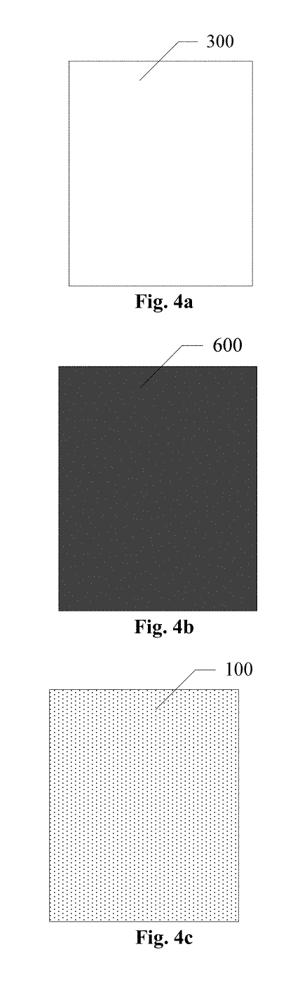

FIG. 2a is a schematic diagram showing steps of the method for manufacturing the display substrate, and FIG. 2b is a schematic diagram showing an exposure operation in the method for manufacturing the black matrix of the display substrate. As shown in FIG. 2a and FIG. 2b, the method includes the following steps S101 to S104.

Step S101: apply a photoresist layer 100 on a base substrate.

For example, the base substrate may be made of at least one of the following: glass, polyimide, makrolon, polyacrylic ester, polyetherimide, polyether sulfone, polyethylene terephthalate and polyethylene naphthalate, which will not be limited in the present embodiment.

For example, prior to applying the photoresist layer 100, the base substrate is cleaned, for example, in a manner of dry cleaning or wet cleaning to enhance an adhesive force and a wettability of the base substrate. For example, the method for cleaning includes ultraviolet rays cleaning, ultrasonic cleaning and the like, but the present embodiment is not limited thereto.

For example, a thin and uniform photoresist layer 100 without defects may be applied on the base substrate using a method of spin-coating, but the present embodiment is not limited thereto, and other coating methods may also be used.

For example, the photoresist includes a resin, a photosensitizer, a solvent and an additive, and prior to exposing, the photoresist layer 100 needs to be prebaked to evaporate the solvent in the photoresist layer 100, thus improving a line resolution after being exposed. The prebaked photoresist layer 100 may be more firmly adhered with the base substrate. For example, a positive photoresist may be prebaked in the air, while a negative photoresist needs to be prebaked in a nitrogen atmosphere.

For example, in the present embodiment, a case where the photoresist layer 100 for forming the black matrix is the negative photoresist layer is described as an example, the exposed portion of the negative photoresist will be hardened due to crosslinking, and may not be dissolved in the developing solution. For example, the material of the negative photoresist may be polyisoprene polymer and the like, but the present embodiment is not limited thereto.

Step S102: subject the photoresist layer 100 to a first exposing operation using a mask 200.

For example, the photoresist may be irradiated using an electron beam, an ion beam, x-rays and ultraviolet rays, but the present embodiment is not limited thereto. For example, the ultraviolet rays may be ordinary ultraviolet rays having a wave length range of 200 nm˜400 nm, and may also be ultraviolet rays having a wave length range of 10 nm˜14 nm, which will not be limited in the present embodiment.

As shown in FIG. 2b, the mask 200 includes a light transmitting portion 201 and a plurality of light shielding portions 202, the plurality of light shielding portions 202 is arranged in an array in a row direction and a column direction, the light shielding portions 202 are arranged in the row direction at intervals of a first distance AA′, and the light shielding portions 202 are arranged in the column direction at intervals of a second distance BB′. For example, the first distance AA′ is a sum of a distance between two adjacent light shielding portions 202 in an X direction (i.e., the row direction) and a size of one light shielding portion 202; the second distance BB′ is a sum of a distance between two adjacent light shielding portions 202 in a Y direction (i.e., the column direction) and the size of one light shielding portion 202.

As shown in FIG. 2b, the photoresist layer 100 is subjected to a first exposing using a mask 200. For example, an ultraviolet ray 500 penetrates through the light transmitting portion 201 of the mask 200 to irradiate a light transmitting region on the photoresist layer 100 formed by the light transmitting portion 201 to make micromolecules located at this portion of the exposure region in the photoresist layer 100 turn into macromolecules, and the polymerized macromolecules cannot be dissolved by the developing solution; the ultraviolet rays 500 are blocked by the light shielding portions 202, and may not irradiate the light shielded regions on the photoresist layer 100 formed by the light shielding portions 202, and the photoresist in these regions will be dissolved by the developing solution during a following developing process.

When subjecting the photoresist layer 100 to the first exposing operation, the light shielded regions on the photoresist layer 100 formed by the plurality of light shielding portions 202 include: a plurality of first light shielded regions 1011 and a plurality of opening structures 101 to be formed, that is, the plurality of opening structures 101 to be formed overlaps the light shielded regions of on the photoresist layer 100 formed by a part of the plurality of the light shielding portions 202, and the first light shielded regions 1011 is located at a side of the plurality of opening structures 101 to be formed on the photoresist layer 100. As shown in FIG. 2b, the light shielded regions on the photoresist layer 100 formed by the plurality of light shielding portions 202 have one more row of the first light shielded regions 1011 than the plurality of opening structures 101 to be formed in the X direction, that is, the plurality of light shielding portions 202 in the mask 200 have one more row of light shielding portions than an ordinary mask in the X direction, but the present embodiment is not limited thereto. For example, it is possible that the light shielded regions on the photoresist layer 100 formed by the plurality of light shielding portions 202 have extra two or more rows of the first light shielded regions 1011 than the plurality of opening structures 101 to be formed in the X direction, and it is also possible that the light shielded regions on the photoresist layer 100 formed by the plurality of light shielding portions 202 have at least one more row of the first light shielded regions than the plurality of opening structures 101 to be formed in the Y direction, or the light shielded regions on the photoresist layer 100 formed by the plurality of light shielding portions 202 have at least one more row of the first light shielded regions than the plurality of opening structures 101 to be formed in the X direction and the Y direction. It should be noted that, the X direction and the Y direction in the present embodiment represent the row direction and the column direction, respectively.

As shown in FIG. 2b, the plurality of opening structures 101 to be formed is indicated by solid-line rectangles, and the first light shielded regions 1011 are indicated by dotted-line rectangles. It should be noted that, the first light shielded regions 1011 herein will not form the final opening structures, therefore are indicated by dotted-line rectangles, and so are the below-mentioned second light shielded regions 1012. FIG. 2b is merely a schematic example, and an actual size of the bezel region at a periphery of the plurality of opening structures 101 may be far larger than a size of each of the opening structures 101.

For example, the light shielding portions 202 in the mask 200 are made of a non-transparent resin or a non-transparent metal material.

Step S103: move the mask 200 a first number of the first distances AA′ in the row direction and a second number of the second distances BB′ in the column direction, and subjecting the photoresist layer 100 to a second exposing operation using the moved mask 200.

As shown in FIG. 2b, when subjecting the photoresist layer 100 to the second exposing operation, the light shielded regions on the photoresist layer 100 formed by the plurality of light shielding portions 202 include a plurality of second light shielded regions 1012 and a plurality of opening structures 101 to be formed. In FIG. 2b, the second light shielded regions 1012 are indicated by dotted-line rectangles, and the second light shielded regions 1012 are located at another side of the plurality of opening structures 101 to be formed with respect to the first light shielded regions 1011. In the present embodiment, a case where the moved distance of the mask 200 in the X direction is the first distance AA′ is described as an example, that is, a case where the plurality of light shielding portions 202 of the mask 200 form on the photoresist layer 100 one more row of light shielded regions than the plurality of opening structures 101 to be formed in the X direction is described, but the present embodiment is not limited thereto. It should be noted that, the plurality of light shielding portions 202 of the mask 200 form on the photoresist layer 100 N rows of light shielded regions more than the plurality of opening structures 101 to be formed in the X direction and/or the Y direction (N is an integer), then the moved distance of the mask 200 in the X direction is N (N is an integer) first distances AA′ and/or the moved distance of the mask 200 in the Y direction is N (N is an integer) second distances BB′.

For example, the moved distance of the mask 200 is an integral multiple of the first distance AA′ and/or an integral multiple of the second distance BB′, which will not be limited in the present embodiment, as long as it is guaranteed that an integrity of the bezel region at the periphery of the black matrix formed during the following process is not affected.

For example, after moving the mask 200 a first distance AA′ in the X direction, when subjecting the photoresist layer 100 to a second exposing operation, the plurality of first light shielded regions 1011 is located at the light transmitting region on the photoresist layer 100 formed by of the light transmitting portion 201, therefore the region where the plurality of first light shielded regions 1011 is located is exposed, the photoresist in this region is exposed and hardened, and may not be dissolved by the developing solution, and thus will not form real opening structures after being developed. Similarly, the photoresist layer 100 in the region where the plurality of second light shielded regions 1012 is located is exposed already during the first exposing operation, the photoresist in this region is hardened due to being exposed, and may not be dissolved by the developing solution, and will not form the real opening structures after being developed either. Therefore, after being exposed twice, only the opening structures 101 to be formed have not been exposed, and finally may form a real pattern having opening structures after being developed, that is, the plurality of opening structures 101 are formed in the region of the photoresist layer 100 shielded during both the first exposing operation and the second exposing, that is, the light shielded regions on the photoresist layer 100 formed by a part of the plurality of light shielding portions 202 during the first exposing operation overlap the light shielding regions on the photoresist layer 100 formed by a part of the plurality of light shielding portions 202 during the second exposing operation.

For example, after being exposed, the photoresist layer 100 needs to be post-baked to cause a thermal motion of the photoresist molecules, and make over-exposed molecules and less-exposed molecules redistributed.

Step S104: develop the photoresist layer 100 to form a pattern having a plurality of opening structures 101.

It should be noted that, in the present embodiment, forming the black matrix of the color filter substrate is described as an example, the photoresist layer 100 in the present embodiment is a black photoresist layer, and the formed photoresist layer 100 having the plurality of opening structures 101 is the black matrix. For example, the black photoresist layer 100 is an acrylic resin mixed with a black pigment (mainly, a carbon), but the present embodiment is not limited thereto.

For example, the photoresist layer 100 is developed using an alkaline developing solution such as sodium bicarbonate (1%), but the present embodiment is not limited thereto.

In the present embodiment, by moving the mask 200 a first number of first distances AA′ in the X direction and a second number of second distances BB′ in the Y direction, and subjecting the photoresist layer 100 to the second exposing operation, even if the mask 200 is contaminated or slightly damaged, a defect in a fixed position will not occur, that is, white defects in a dark region will not be generated at locations where the black matrix is supposed to be located, thus effectively reducing the loss of utilization rate and increasing a yield of the black matrix during the process, saving costs, and reducing risk.

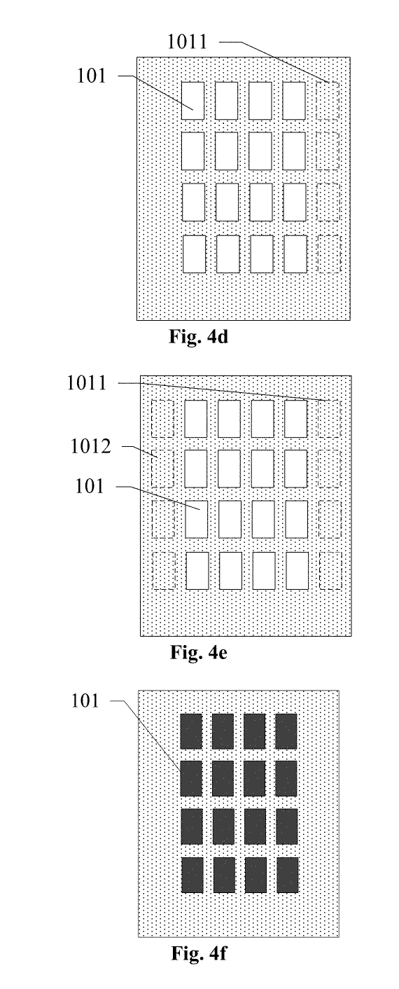

FIG. 3 is a schematic diagram showing an exposure process in a case where there is a foreign matter on the mask. As shown in FIG. 3, in the case that there is a foreign matter 400 on the mask 200, when subjecting the photoresist layer 100 to the first exposing operation, the shielded region on the photoresist layer 100 formed by the foreign matter 400 is a first foreign matter shielded region 401; moving the mask 200 a first distances AA′ in the X direction, and subjecting the photoresist layer 100 to a second exposing operation using the moved mask 200, wherein the shielded region on the photoresist layer 100 formed by the foreign matter 400 is a second foreign matter shielded region 402. The first foreign matter shielded region 401 and the second foreign matter shielded region 402 will not form the final foreign matter pattern, therefore are indicated by dotted-line boxes. It should be noted that, FIG. 3 is merely a schematic example, and it is also possible to move the mask 200 a plurality of first distances AA′ in the X direction and/or at least one second distance BB′ in the Y direction, but the present embodiment will not be limited thereto.

After moving the mask 200 one first distance AA′ in the X direction, the first foreign matter shielded region 401 is located at the light transmitting region of the photoresist layer 100 formed by the light transmitting portion 201, therefore, during the second exposing operation, the location where the first foreign matter shielded region 401 is on the photoresist layer 100 will be exposed, the photoresist in this region will be hardened due to being exposed, and will not be dissolved by the developing solution, therefore the first foreign matter shielded region 401 formed during the first exposing operation will not become a bright spot after being developed. Similarly, the photoresist layer 100 in the region where the second foreign matter shielded region 402 is located during the second exposing operation is exposed already during the first exposing operation, the photoresist in this region is hardened due to being exposed, and will not be dissolved by the developing solution, and will not become a bright spot after being developed. Therefore, even if the mask 200 is contaminated or slightly damaged, after being exposed twice, the foreign matters on the mask 200 will not produce defect marks on the photoresist layer 100, thus increasing the yield of the black matrix, and lowering the operation loss.

For example, in case that there are foreign matters at two locations on the mask, and the foreign matters at the two locations overlap after being moved, the black matrix manufactured by the method for manufacturing the display substrate according to the present embodiment enables the case where there are two foreign matter patterns to be improved to a case where there is only one foreign matter pattern, thus also increasing the yield of the black matrix during the process.

For example, in general, the bright spot occurs at the bezel region of the black matrix needs to be manually repaired (by an ink repairing operation), which wastes resources. The method for manufacturing the display substrate according to the present embodiment may reduce the operation loss caused by the bright spot generated at the bezel region, thus eliminating repairing steps, and increasing the working efficiency.

It should be noted that, FIG. 3 shows a case where the first foreign matter shielded region 401 or the second foreign matter shielded region 402 generated by the foreign matters 400 is located at the bezel region of the black matrix as an example, and the black matrix manufactured by the method for manufacturing the display substrate may effectively avoid the bright spot generated at the bezel region of the black matrix, but the present embodiment is not limited thereto. For example, it is also possible that the foreign matter patterns generated by foreign matters are located at the pixel region of the black matrix, therefore, the black matrix manufactured by the method for manufacturing display substrate may effectively avoid light leakage at the pixel region, thus effectively reducing the operation loss and increasing the yield of the black matrix during the process.

For example, after forming the black matrix, each of color layers is formed. For example, a red (R) layer, a green (G) layer and a blue (B) layer are formed, and each of the color layers may include a polymer, a monomer, a solvent, a pigment, a photoinitiator, a dispersing agent and the like, but the present embodiment is not limited thereto.

For example, a layer of R coloring sensitive material is applied on the pattern of the black matrix layer, the R coloring sensitive material includes R pigment dispersed in an acrylic resin or an epoxy resin capable of being hardened using ultraviolet rays, and exists as a liquid when being used. The coated R coloring sensitive material is subjected to a photoetching operation using a R mask (a mask for forming a R pixel layer), and the exposed region may not be dissolved in the alkaline developing solution such as sodium bicarbonate (1%), but the present embodiment is not limited thereto. The unexposed region will not be hardened, and may be dissolved in the alkaline developing solution, and then may be removed. After being developed, a required pattern of the R color layer is left. Repeating the above steps, a pattern of G color layer and a pattern of B color layer may be obtained. An order of the formation of the patterns of color layer is not limited in the present embodiment.

For example, in the step of performing exposing operations using the mask to form the patterns of color layers, a single mask may be used in the exposing operations for the three color layers according to a design of different shapes and arrangements of pixel regions, and different masks may also be used in the exposing operations for the three color layers, which will not be limited in the present embodiment.

For example, in the present embodiment, steps of forming the black matrix and forming color filter layers of different colors are included, and a color filter substrate may be prepared according to the method. However, the embodiment according to the present disclosure is not limited thereto, the black matrix may also be formed on an array substrate, and therefore an array substrate having the black matrix may also be manufactured according to the above method.

For example, in the present embodiment, a method for manufacturing the black matrix having the plurality of opening structures by means of a patterning process is described as an example, but the present embodiment is not limited thereto, for example, other pattern layers having the plurality of opening structures such as a pixel defining layer may also be formed by the manufacturing method.

Unlike the above embodiments, the photoresist layer applied on the base substrate according to the present embodiment may not be a black photoresist layer, instead, may be used as a mask for etching the black material to form the black matrix having the plurality of opening structures. In the method for manufacturing the display substrate according to the present embodiment, a black material layer 600 is formed on the base substrate 300, prior to applying the photoresist layer 100 on the base substrate 300.

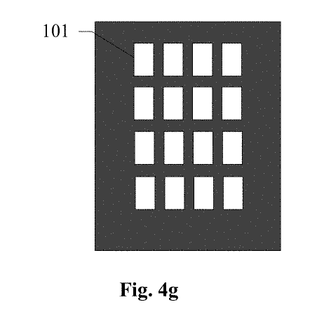

FIG. 4a to FIG. 4g are schematic diagrams showing process steps in a manufacturing flow of the black matrix according to the present embodiment. FIG. 4a shows a base substrate 300 after being cleaned, and FIG. 4b shows a black material layer 600 formed on the base substrate 300, for example, the black material layer 600 includes chrome and the like, but the present embodiment is not limited thereto.

As shown in FIG. 4c, a photoresist layer 100 is applied on the black material layer 600, for example, the photoresist layer 100 may be a transparent photoresist, but the present embodiment is not limited thereto.

FIG. 4d to FIG. 4f show a process of forming a pattern having a plurality of opening structures 101 through exposing the photoresist layer 100 twice and developing the photoresist layer 100, which is identical to the embodiment shown in FIG. 2a to FIG. 2b, and will not be repeated herein.

As shown in FIG. 4g, the black material layer 600 is etched by using the photoresist layer 100 having the plurality of opening structures 101 as a mask to form the black matrix having the plurality of opening structures 101. For example, the black material layer 600 may be etched into a required pattern by dry etching or wet etching. Dry etching includes plasma etching, for example. For example, in case that dry etching is used, the plurality of opening structures 101 penetrating through the black material layer 600 may be formed in the black material layer 600 by plasma etching. It should be noted that, methods for forming the plurality of opening structures 101 penetrating through the black material layer 600 in the black material layer 600 are not limited to the above.

A black matrix may be manufactured using the method for manufacturing the display substrate, even if the mask for manufacturing the black matrix is contaminated or slightly damaged, a defect in a fixed position will not occur, such that a problem that the black matrix generates light leakage or a bright spot at a pixel region or a bezel region may be effectively solved, thus effectively reducing the loss of utilization rate and increasing a yield of the black matrix during the process, saving costs and reducing risk.

The present embodiment provides a display substrate, and the display substrate is manufactured by any one of the methods for manufacturing the display substrate according to the embodiments of the present disclosure.

For example, the display substrate may be a color filter substrate or an array substrate, which is not be limited in the present embodiment. For example, the photoresist layer having a plurality of opening structures formed on the display substrate may be a black matrix of the color filter substrate, and may also be a pixel defining layer in an array substrate in an organic light emitting diode, which is not be limited in the present embodiment.

The black matrix in the display substrate is manufactured by using any one of the methods for manufacturing the display substrate according to the embodiments of the present disclosure. The black matrix has a high manufacturing yield rate, and will not generate a defect in a fixed position, that is, the probability of occurrence of light leakage and a bright spot at the pixel region and the bezel region is low.

The present embodiment provides a display device, including any one of the display substrates according to the embodiments of the present disclosure. The display device has a low probability of occurrence of light leakage and a bright spot at the pixel region and the bezel region. The black matrix in the display device may effectively intercept leaked light between sub-pixels, avoid a color mixture of color layers connected to each other, and reduce reflecting of external light, thus improving a contrast ratio of the display device.

For example, the display device may be a liquid crystal display device, an electronic paper, an organic light-emitting diode (OLED) display and any products or components having a display function, such as a TV, a digital camera, a mobile phone, a watch, a tablet PC, a notebook computer, a navigator including the display device, but the present embodiment is not limited thereto.

The following should be noted:

(1) Unless otherwise defined, in the embodiments and drawings of the present disclosure, the same reference number has the same meaning.

(2) In the embodiments and drawings of the present disclosure, only structures related to the embodiments of the present disclosure are involved, and reference may be made to ordinary design for other structures.

(3) For clarity, in the drawings for describing the embodiments of the present disclosure, layers or regions are exaggerated. It should be understood that, when it is mentioned that one element such as a layer, a film, a region or a substrate is located “on/above”, “under/below” another element, the element may be “directly” located “on/above”, “under/below” another element, or there may be an intervening element.

The above are merely some embodiments of the present disclosure and shall not be used to limit the scope of the present disclosure. A person skilled in the art may readily envisage modifications and replacements without departing from the scope disclosed by the present disclosure, and these modifications and replacements shall also fall within the scope of the present disclosure. The scope of the present disclosure should be limited by the attached claims.

What is claimed is:

1. A method for manufacturing a display substrate, comprising:
applying a photoresist layer on a base substrate;
subjecting the photoresist layer to a first exposing operation using a mask, wherein the mask comprises a light transmitting portion and a plurality of light shielding portions, the plurality of light shielding portions is arranged in an array in a row direction and a column direction, the light shielding portions are arranged in the row direction at intervals of a first distance, and the light shielding portions are arranged in the column direction at intervals of a second distance;
moving the mask a first number of the first distances in the row direction and a second number of the second distances in the column direction, and subjecting the photoresist layer to a second exposing operation using the moved mask; and
developing the photoresist layer to form a pattern having a plurality of opening structures.

2. The method according to claim 1, wherein the plurality of opening structures is formed at a region of the photoresist layer shielded during the first exposing operation and the second exposing operation.

3. The method according to claim 1, wherein the plurality of opening structures and a light shielded region on the photoresist layer formed by a part of the plurality of light shielding portions overlap.

4. The method according to claim 1, wherein the display substrate is a color filter substrate.

5. The method according to claim 4, wherein the photoresist layer is a black photoresist layer, and the black photoresist layer having the plurality of opening structures is a black matrix.

6. The method according to claim 4, further comprising:
forming a black material layer on the base substrate, prior to applying the photoresist layer on the base substrate.

7. The method according to claim 6, comprising etching the black material layer by using the photoresist layer having the plurality of opening structures as a mask to form the black matrix having the plurality of opening structures.

8. The method according to claim 6, wherein the black material layer comprises chrome.

9. The method according to claim 1, wherein the photoresist layer is a negative photoresist layer.

10. The method according to claim 1, wherein the first number and the second number are integers.

11. The method according to claim 1, wherein the plurality of light shielding portions of the mask is made of a non-transparent resin or a non-transparent metal material.

12. The method according to claim 10, wherein
the first number is zero, or
the second number is zero.
